(19) United States
(12) Patent Application Publication
(10) Pub. No.: US 2019/0023618 A1
(43) Pub. Date: Jan. 24, 2019

(54) COMPOSITE MATERIAL AND METHOD FOR MAKING

(71) Applicant: GENERAL ELECTRIC COMPANY, Schenectady, NY (US)

(72) Inventor: Gregory Scot Corman, Ballston Lake, NY (US)

(21) Appl. No.: 16/140,906

(22) Filed: Sep. 25, 2018

Related U.S. Application Data
(62) Division of application No. 15/355,749, filed on Nov. 18, 2016.

(51) Int. Cl. C04B 35/80; C04B 35/653; C04B 35/65; C04B 35/628; C04B 35/58; C04B 35/565; C04B 35/563; C23C 16/04

(52) U.S. Cl. CPC C04B 35/806; C04B 2235/80; C04B 2235/728; C04B 2235/616; C04B 2235/526; C04B 2235/5248; C04B 2235/524; C04B 2235/422; C04B 2235/421; C04B 2235/3873; C04B 2235/3826; C04B 2235/3821; C04B 35/653; C04B 35/65; C04B 35/62873; C04B 35/62868; C04B 35/58085; C04B 35/565; C04B 35/563; C23C 16/045; C04B 2235/614; C04B 2235/5244; C04B 2235/386

(57) ABSTRACT

A method for making a composite material includes disposing a quantity of liquid comprising at least 90 weight percent molten boron within pores of a porous preform, the preform comprising a preform material; and reacting at least a portion of the molten boron with a portion of the preform material to form a solid ceramic reaction product, thereby forming a ceramic matrix composite material. An article comprises a composite material; the composite material comprises a fibrous phase disposed within a matrix. The matrix comprises silicon carbide, boron carbide, and boron silicide.

### BACKGROUND

This disclosure relates to materials for use in high temperature applications, such as for gas turbine assembly components. More particularly, this disclosure relates to ceramic matrix composite materials and methods for making such materials.

Ceramic matrix composites (CMC's) generally include a ceramic fiber reinforcement material embedded in a ceramic matrix material. The reinforcement material serves as the load-bearing constituent of the CMC in the event of a matrix crack, while the ceramic matrix protects the reinforcement material, maintains the orientation of its fibers, and serves to dissipate loads to the reinforcement material. Of particular interest to high-temperature applications, such as in gas turbines, are silicon-based composites, which include silicon carbide (SiC) as the matrix and/or reinforcement material.

Different processing methods have been employed in forming CMCs. For example, one approach includes melt infiltration (MI), which employs a molten silicon to infiltrate into a fiber-containing perform. CMCs formed by MI are generally fully dense, e.g., having nominally zero residual porosity. Another approach for forming CMCs is chemical vapor infiltration (CVI). CVI is a process whereby a matrix material is infiltrated into a fibrous preform using reactive gases at elevated temperature to form the fiber-reinforced composite. Generally, limitations introduced by having reactants diffuse into the preform and by-product gases diffusing out of the perform result in relatively high residual porosity of between about 10 percent and about 15 percent in the composite. In particular, typically in forming CMCs using CVI, the outer portion of the composite formed by CVI typically has a lower porosity than the porosity of the inner portion of the composite. Another approach for forming CMCs includes initially employing a partial CVI process followed by a MI process. This approach usually yields lower residual porosity of between about 5 percent and about 7 percent. However, processes that employ MI with silicon as the infiltrant typically result in a small but significant amount of residual unreacted silicon; the use of the resulting CMC material is thus generally limited to temperatures below the melting point of the residual silicon.

There is therefore a need for CMC's having a low-porosity matrix with use temperature above the melting point of silicon.

### BRIEF DESCRIPTION

Embodiments of the present invention are provided to meet this and other needs. One embodiment is a method for making a composite material. The method comprises disposing a quantity of liquid comprising at least 90 weight percent molten boron within pores of a porous preform, the preform comprising a preform material; and reacting at least a portion of the molten boron with a portion of the preform material to form a solid ceramic reaction product, thereby forming a ceramic matrix composite material.

Another embodiment is an article comprising a composite material; the composite material comprises a fibrous phase disposed within a matrix. The matrix comprises silicon carbide, boron carbide, and boron silicide.

### DRAWINGS

These and other features, aspects, and advantages of the present invention will become better understood when the following detailed description is read with reference to the accompanying drawing in which like characters represent like parts, wherein:

FIG. 1 is a cross-sectional representation of a preform in accordance with some embodiments of the present invention; and

FIG. 2 is a cross-sectional representation of an article in accordance with some embodiments of the present invention.

### DETAILED DESCRIPTION

Approximating language, as used herein throughout the specification and claims, may be applied to modify any quantitative representation that could permissibly vary without resulting in a change in the basic function to which it is related. Accordingly, a value modified by a term or terms, such as “about”, and “substantially” is not to be limited to the precise value specified. In some instances, the approximating language may correspond to the precision of an instrument for measuring the value. Here and throughout the specification and claims, range limitations may be combined and/or interchanged; such ranges are identified and include all the sub-ranges contained therein unless context or language indicates otherwise.

In the following specification and the claims, the singular forms “a”, “an” and “the” include plural referents unless the context clearly dictates otherwise. As used herein, the term “or” is not meant to be exclusive and refers to at least one of the referenced components being present and includes instances in which a combination of the referenced components may be present, unless the context clearly dictates otherwise.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances, the modified term may sometimes not be appropriate, capable, or suitable.

Embodiments of the present invention include those that employ melt infiltration (MI) techniques, but with boron as a primary constituent of the infiltrant instead of silicon. Boron has a significantly higher melting temperature (2076 degrees Celsius) than silicon (1414 degrees Celsius), and forms various compounds with, for example, silicon and carbon, that have attractive properties for high temperature applications.

One embodiment of the present invention includes a method for making a composite material. The method includes a MI technique, wherein molten boron-bearing material is disposed in a preform and then reacted with preform material to form a solid ceramic reaction product. As used herein, the term “ceramic” is intended to include, but not to be limited to, silicides, nitrides, carbides, and oxides.

The method includes disposing a quantity of liquid within pores of a porous preform. The liquid may include other constituents besides boron, but boron is the primary constituent of the liquid by weight. In certain embodiments, the liquid comprises at least 90 weight percent boron. Other constituents may be included to, for example, enhance the ability of the melt to wet, infiltrate, and/or react with the preform material. Potential candidates for other constituents include carbon, silicon, and various transition metals. The other constituents should not be present in amounts that may form deleterious phases during subsequent reaction steps or that may leave unreacted residual material in the resulting CMC that unduly detracts from the high temperature performance of the CMC. In particular embodiments, the liquid is nominally pure elemental boron, meaning that the liquid includes boron and only incidental impurities; here the potential for formation of deleterious phases is reduced due to the lack of other constituents.

Disposing the liquid in the pores of the preform is accomplished in some embodiments by a melt infiltration technique similar in principle to the techniques used for conventional silicon melt infiltration. In one example, a preform is disposed in a furnace, such as a vacuum furnace, with the preform in contact with a source of boron. The preform is heated to above the melting temperature of the boron source. Once it is heated to a temperature above its melting point, the source provides molten material that infiltrates into the porous preform by capillary action. In one embodiment, this infiltration occurs in an inert environment, such as in vacuum, to avoid undesirable oxidation or other potentially harmful interactions between or among the ambient environment, the liquid, and/or the preform material. In some embodiments, the infiltration is performed at a temperature greater than 1500 degrees Celsius, and in particular embodiments, the temperature is at least 2000 degrees Celsius.

As used herein, the term “preform” is intended to broadly encompass any structure suitable for the formation of a CMC in accordance with the described techniques, and is not intended to limit the structure to only those formed by a particular technique. The preform is porous, meaning it comprises a plurality of internal voids that are in fluid communication with the exterior of the preform. In some embodiments, the preform includes at least 10 percent porosity by volume, and in certain embodiments the porosity is at least 20 percent by volume. A high level of porosity enables more efficient infiltration, but porosity should not be so high, for example, as to yield a preform with unacceptable mechanical integrity. In some embodiments, porosity is less than 35 percent by volume and in particular embodiments, porosity is less than 30 percent by volume.

The preform comprises a preform material. The preform material typically includes a portion of material that reacts with the liquid to form the solid reaction product that eventually resides in the matrix portion of the resultant CMC. The preform material also typically includes a portion of material that remains unreacted and provides the reinforcement portion of the resultant CMC. In some embodiments, the preform material comprises silicon carbide, carbon, boron carbide, boron nitride, or a combination including one or more of the foregoing. These materials have attractive properties for use in high temperature materials such as CMC's. In particular embodiments, the preform material includes silicon carbide. This material is used extensively as a reinforcement material in CMC's due to its comparatively low density and high temperature mechanical properties. Moreover, silicon carbide is expected to react with boron to form boron carbide and silicon boride ceramic reaction products, which materials have attractive density and chemical compatibility with silicon carbide at elevated temperatures.

Typically, though not necessarily, the preform comprises a plurality of fibers. The fibers may be continuous, as found in, for instance, unidirectionally reinforced plies or in woven cloth plies; the fibers alternatively may be chopped into sufficiently short lengths to allow them to be randomly oriented within the preform. Generally, the term “continuous” as used herein refers to fibers of length greater than 1 cm and having an orientation within the preform that is non-random.

The fibers of the preform may further comprise at least one coating disposed on a surface of the fibers. The coating(s) (also referred to herein as “protective coating”) may be applied to inhibit reaction between the fiber material and the liquid during infiltration, and/or to promote a low-strength interface between the fiber and the matrix of the resultant CMC material, thereby imparting toughness to the CMC material. Examples of suitable coating materials include, without limitation, boron nitride, silicon-doped boron nitride, elemental carbon, and any suitable combination including one or more of the foregoing. These coatings may be applied using any suitable technique, such as chemical vapor deposition. The thickness and structure of the coating may be selected based at least in part on the type of material, the nature of the infiltrant, and the infiltration time and temperature—all which considerations will be familiar to practitioners in the composite processing art.

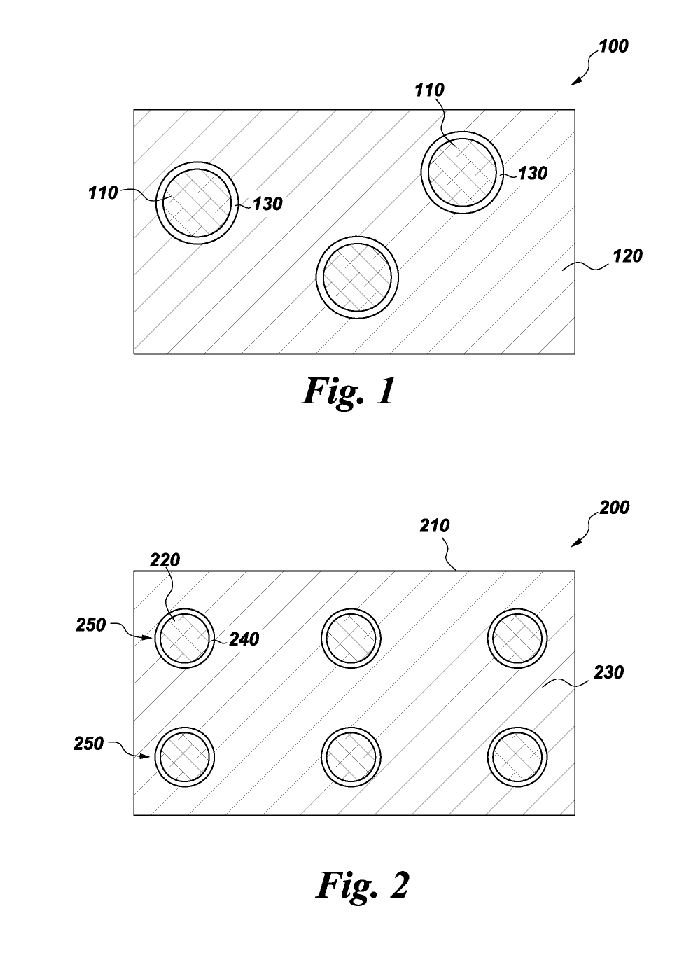

In certain embodiments, the protective coating on the fibers separates the portion of the preform that is intended to react with the liquid (“reactant material”) from the portion of the preform that is intended to remain unreacted. Therefore, referring now to the illustrative cross section in FIG. 1, in some embodiments the preform 100 comprises a plurality of fibers 110, a quantity of reactant material 120, and a coating material 130 interposed between the fibers 110 and the reactant material 120. The reactant material 120 may include, for example, silicon carbide, carbon, or any combination including one or both of these. In certain embodiments, the reactant material 120 is in particulate form, and may further include a binder material to facilitate disposing the reactant material over the coated fibers 110.

Any of the various methods known in the composite materials processing art for forming a porous preform may be applied to the present technique. For example, a scaffold comprising a plurality of fibers is formed, and then an additional material, such as reactant material, is disposed on the scaffold to form the preform. This fibrous scaffold may comprise unidirectional fiber plies, woven fiber cloth, wound or braided three-dimensional shapes, or other suitable fiber architecture commonly applied in the art of composite fabrication. The fibers may be coated with protective coating(s) prior to being formed into the scaffold, or the scaffold may be formed of uncoated fibers, then the scaffold itself is coated prior to the disposition of the additional material.

In one embodiment, the additional material, such as material comprising silicon carbide, for instance, is disposed on the scaffold via a chemical vapor infiltration (CVI) process. In a CVI process, a vapor precursor is introduced into the scaffold at an elevated temperature, causing a chemical reaction that results in deposition of the additional material onto the scaffold to form the prefrom. CVI processes for deposition of silicon carbide, for example, are widely used and well known in the art of composite fabrication.

In another example, a slurry-cast method is used to deposit the additional material. In this method, the scaffold is formed to shape, and then, often after applying the protective coating(s) to the fiber scaffold, the additional material, such as a material comprising silicon carbide, is disposed on the scaffold by slurry casting. In slurry casting, particles of the additional material are dispersed in a carrier liquid to form a slurry, and this slurry is disposed on the scaffold. Upon volatilization of the carrier liquid, the additional material remains on the scaffold to form the porous preform. This additional material may participate in a chemical reaction with the liquid during subsequent infiltration to form phases found in the matrix of the final CMC product.

In yet another example, forming the preform follows a method similar to the well-known “prepreg” process. In the prepreg process, a tow of fiber (often including protective coating(s) on the fiber) is pulled through a slurry containing the additional material, binders, and solvents, and then wound on a drum to form a unidirectional pre-impregnated, i.e., “prepreg,” tape. The tape, which comprises the fibers disposed in a matrix that includes the additional material, is then dried, removed from the drum, cut to shape, laid-up to give the desired fiber architecture, and laminated to form a green composite preform. Thus, in some embodiments of the present invention, forming the preform includes forming a plurality of plies comprising unidirectional fibers; and laminating the plies. The fibers and the additional material respectively may comprise any of the materials described previously. The additional material, as noted previously, may participate in a chemical reaction with the liquid during infiltration to form phases found in the matrix of the final CMC product.

As the liquid infiltrates the porous preform, it reacts with a portion of the preform material to form a solid ceramic reaction product, thereby forming a ceramic matrix composite material. Typically, though not exclusively, the portion of the preform material that reacts with the liquid is the additional material described above. For example, as noted previously, the boron in the liquid may react with silicon carbide to form boron carbide and silicon boride ceramic reaction products. The resultant ceramic matrix composite material, then, would include a matrix comprising these reaction products, and a fibrous phase disposed within the matrix. The matrix may further include residual, unreacted reactant material, such as silicon carbide.

Referring now to FIG. 2, in one embodiment an article 200 comprises a composite material 210. Material 210 comprises a fibrous phase 220 disposed within a matrix 230. The matrix 230 comprises one or more ceramic phases, such as materials noted above that may be formed as a result of the reaction between the liquid and the preform material. In particular embodiments, matrix 230 comprises boron carbide and boron silicide. Matrix 230 may also include silicon carbide, such as in cases where residual silicon carbide material remains unreacted after infiltration. Moreover, in some embodiments matrix 230 further comprises elemental boron, such as in cases where residual boron remains unreacted after infiltration. Because boron has a significantly higher melting point than silicon, having unreacted elemental boron present in material 210 does not limit the operating temperature of material 210 to the same degree as having unreacted elemental silicon limits operating temperatures for conventional melt infiltrated CMC.

As used herein, a “fibrous phase” means a phase having a length that is much larger than its width. Typical fibrous phases have an aspect ratio of greater than 20 for short (chopped) fiber, and often greater than 200 for long (“continuous”) fiber. In some embodiments, the fibrous phase 220 has a nominal fiber length of at least one centimeter. The fibrous phase 220 in embodiments of the present invention is made of material that is intentionally added to the composite, in contrast to phases that form in situ due to chemical reactions and/or phase transformations. The fibrous phase 220 typically comprises one or more materials suitable to provide desired levels of mechanical strength at elevated temperatures. Examples of such materials include, without limitation, silicon carbide, carbon, boron carbide, and boron nitride. Silicon carbide is a particular example of a material used effectively in CMC materials as a primary component of the reinforcing fiber.

Typically, the amount of fibrous phase present in the CMC is selected to provide the desired balance of properties for a given application, where a higher volume fraction of fibrous phase tends to produce stronger material. Depending on the architecture of the composite, however, increasing the amount of fiber may detract from certain properties, such as interlaminar strength (in laminated architectures), or toughness. In some embodiments, the fibrous phase is present in the composite material in a volume fraction in a range from about 10 percent to about 50 percent of the volume of the composite material. In certain embodiments, the range is from about 15 percent to about 40 percent, and in particular embodiments the range is from about 20 percent to about 35 percent.

As noted previously, coatings are often disposed on fibers in CMC materials to inhibit reaction between the fiber material and the liquid during infiltration, and/or to promote a low-strength interface between the fiber and the matrix of the resultant CMC material, thereby imparting toughness to the CMC material. In the embodiment illustrated in FIG. 2, composite material 210 further comprises at least one coating 240 disposed on a surface of fibrous phase 220. Coating 240 comprises any material suitable to perform the above-noted function; examples of suitable coating materials include, without limitation, boron nitride, silicon-doped boron nitride, elemental carbon, and any suitable combination including one or more of the foregoing. These coatings may be applied using any suitable technique, such as chemical vapor deposition. The thickness and structure of the coating may be selected based at least in part on the type of material, the nature of the infiltrant, and the infiltration time and temperature—all which considerations will be familiar to practitioners in the composite processing art.

Composite material 210 is particularly useful in applications demanding high strength at elevated temperatures, with a lower density than typical superalloys and other metals. For example, article 200 may be any of various components of a gas turbine assembly, including for instance, turbine blades and vanes, shrouds, combustor liners, and any other component that benefits from the advantages conferred by the material 210.

One example of such an article 200 comprises a composite material 210, which material 210 comprises a fibrous phase 220 disposed within a matrix 230. Matrix 230 comprises silicon carbide, boron carbide, and boron silicide. The fibrous phase 220 has a nominal fiber length of at least one centimeter. Fibrous phase 220 comprises silicon carbide and further comprises at least one coating 240 disposed on a surface of the fibrous phase. In particular embodiments, material 210 includes a plurality of laminated plies 250, though of course the final structure of material 210 will depend in large part on which method was employed in fabricating material 210.

### EXAMPLES

The following examples are presented to further illustrate non-limiting embodiments of the present invention.

In one illustrative method, tows of silicon carbide fiber are coated with at least one protective coating, such as with one or more layers of boron nitride. The coated tows are then “prepregged” using techniques typically applied to conventional silicon carbide-based CMC processing. For instance, the tows are pulled through a slurry which typically includes one or more matrix constituents and/or precursors (such as, for instance, particles of silicon carbide) along with organic binders and/or carrier liquid, to form unidirectional prepreg tape. The prepreg tape is cut and laid up in a series of plies to form an uncured scaffold which is then consolidated such as in an autoclave under heat and pressure. The consolidated scaffold is subject to a burn-out process to form a porous preform. The cured perform is subjected to a chemical vapor infiltration (CVI) to deposit silicon carbide on and within the cured preform, resulting in a volume porosity of about 8 percent to about 35 percent. Further densification is then achieved with a melt infiltration process to form a ceramic matrix composite article. The melt infiltration is performed by placing a source of boron, such as one or more pieces of elemental boron, in contact with the preform in a vacuum furnace, then heating the preform above the melting point of the boron source. A ceramic matrix composite article formed by this method may have a volume porosity of less than about 5 percent, and may include silicon carbide fibers (with protective coating) disposed in a matrix that includes the product of chemical reaction between the liquid boron and the silicon carbide deposited by CVI. Residual unreacted silicon carbide and/or boron may also reside in the matrix. Such a ceramic matrix composite article may be advantageous for application to turbine components, for example, turbine blades, vanes, nozzles, shrouds, combustors, etc., and repairs thereof.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A method for making a composite material, the method comprising:
disposing a quantity of liquid comprising at least 90 weight percent molten boron within pores of a porous preform, the preform comprising a preform material; and
reacting at least a portion of the molten boron with a portion of the preform material to form a solid ceramic reaction product, thereby forming a ceramic matrix composite material.

2. The method of claim 1, wherein the preform material comprises silicon carbide, carbon, boron carbide, boron nitride, or a combination including one or more of the foregoing.

3. The method of claim 1, wherein the preform material comprises silicon carbide.

4. The method of claim 1, wherein the preform material comprises a plurality of fibers.

5. The method of claim 4, wherein the fibers further comprise at least one coating disposed on a surface of the fibers.

6. The method of claim 5, wherein the at least one coating comprises boron nitride, silicon-doped boron nitride, elemental carbon, or a combination including one or more of the foregoing.

7. The method of claim 1, further comprising
forming a scaffold comprising fibers, the fibers comprising silicon carbide; and
disposing an additional material comprising silicon carbide on the scaffold via chemical vapor infiltration to form the preform.

8. The method of claim 1, further comprising
forming a scaffold comprising fibers, the fibers comprising silicon carbide; and
slurry casting an additional material comprising silicon carbide onto the fibers to form the preform.

9. The method of claim 1, further comprising
forming the preform, wherein forming the preform comprises
forming a plurality of plies comprising unidirectional fibers; and
laminating the plies.

10. The method of claim 1, wherein disposing comprises introducing the molten boron into the pores of the preform from a boron source via capillary action.
